(19) United States
(12) Patent Application Publication
(10) Pub. No.: US 2026/0188198 A1
(43) Pub. Date: Jul. 2, 2026

(54) DISPLAY MODULE AND ELECTRONIC DEVICE INCLUDING THE SAME

(71) Applicant: SAMSUNG DISPLAY CO., LTD., YONGIN-SI (KR)

(72) Inventors: JAEKEUN LIM, Yongin-si (KR); HAE-KWAN SEO, Yongin-si (KR); JIN-WOOK YANG, Yongin-si (KR)

(21) Appl. No.: 19/428,475

(22) Filed: Dec. 22, 2025

(30) Foreign Application Priority Data
Dec. 31, 2024 (KR) 10-2024-0202488

(51) Int. Cl. G09G 3/32

(52) U.S. Cl. CPC G09G 3/32; G09G 2300/0426; G09G 2300/0465; G09G 2310/0267; G09G 2310/0275; G09G 2320/0233; G09G 2330/021

(57) ABSTRACT

A display device includes a first data line that receives a first color data signal or a second color data signal, a second data line that receives a third color data signal, a first-first scan line that receives a first-first scan signal, a second-first scan line that receives a second-first scan signal, a first-first pixel circuit that receives the first color data signal in response to the first-first scan signal, a second-first pixel circuit that receives the second color data signal in response to the second-first scan signal, a third-first pixel circuit that receives the third color data signal in response to the first-first scan signal, and a fourth-first pixel circuit that receives the third color data signal in response to the second-first scan signal.

### CROSS-REFERENCE TO RELATED APPLICATIONS

This application claims priority under 35 U.S.C. § 119 to Korean Patent Application No. 10-2024-0202488, filed on Dec. 31, 2024, the disclosure of which is incorporated by reference herein in its entirety.

### TECHNICAL FIELD

Embodiments of the present disclosure relate to a display module with reduced power consumption and an electronic device including the same.

### DISCUSSION OF RELATED ART

Multimedia electronic devices, such as, for example, a television, a mobile phone, a tablet computer, a car navigation device, a video game console, and the like, include a display module (or, display device) that displays an image. The display module includes a display panel and a display panel driver. The display panel driver includes a scan driver that provides scan signals to a plurality of scan lines and a data driver that provides data voltages to a plurality of data lines.

### SUMMARY

Embodiments of the present disclosure provide a display module (also referred to as a display device) with reduced power consumption and an electronic device including the same.

According to an embodiment, a display device includes a first data line that receives a first color data signal or a second color data signal, a second data line that receives a third color data signal, a first-first scan line that receives a first-first scan signal, a second-first scan line that receives a second-first scan signal, a first-first pixel circuit that is connected to the first data line and the first-first scan line and that receives the first color data signal in response to the first-first scan signal, a second-first pixel circuit that is connected to the first data line and the second-first scan line and that receives the second color data signal in response to the second-first scan signal, a third-first pixel circuit that is connected to the second data line and the first-first scan line and that receives the third color data signal in response to the first-first scan signal, a fourth-first pixel circuit that is connected to the second data line and the second-first scan line and that receives the third color data signal in response to the second-first scan signal, a first-first light-emitting element that is connected to the first-first pixel circuit and that outputs light of a first color, a second-first light-emitting element that is connected to the second-first pixel circuit and that outputs light of a second color, a third-first light-emitting element that is connected to the third-first pixel circuit and that outputs light of a third color, and a fourth-first light-emitting element that is connected to the fourth-first pixel circuit and that outputs the light of the third color.

According to an embodiment, the display device includes a first scan line that extends in a first direction, a second scan line that extends in the first direction, a first data line that extends in a second direction crossing the first direction, a second data line that extends in the second direction, a first pixel circuit connected to the first data line and the first scan line, a second pixel circuit connected to the first data line and the second scan line, a third pixel circuit connected to the second data line and the first scan line, a fourth pixel circuit connected to the second data line and the second scan line, a first light-emitting element that is connected to the first pixel circuit and that outputs light of a first color, a second light-emitting element that is connected to the second pixel circuit and that outputs light of a second color, a third light-emitting element that is connected to the third pixel circuit and that outputs light of a third color, and a fourth light-emitting element that is connected to the fourth pixel circuit and that outputs the light of the third color.

The first to fourth pixel circuits are sequentially arranged in the first direction, and the first light-emitting element, the third light-emitting element, the second light-emitting element, and the fourth light-emitting element are sequentially arranged in the first direction.

According to an embodiment, an electronic device includes a display device that displays an image based on an image signal and a processor that controls driving of the display device and provides the image signal to the display module.

The display device includes a first scan line that extends in a first direction, a second scan line that extends in the first direction, a first data line that extends in a second direction crossing the first direction, a second data line that extends in the second direction, a first pixel circuit connected to the first data line and the first scan line, a second pixel circuit connected to the first data line and the second scan line, a third pixel circuit connected to the second data line and the first scan line, a fourth pixel circuit connected to the second data line and the second scan line, a first light-emitting element that is connected to the first pixel circuit and that outputs light of a first color, a second light-emitting element that is connected to the second pixel circuit and that outputs light of a second color, a third light-emitting element that is connected to the third pixel circuit and that outputs light of a third color, and a fourth light-emitting element that is connected to the fourth pixel circuit and that outputs the light of the third color.

The first to fourth pixel circuits are sequentially arranged in the first direction, and the first light-emitting element, the third light-emitting element, the second light-emitting element, and the fourth light-emitting element are sequentially arranged in the first direction.

### BRIEF DESCRIPTION OF THE DRAWINGS

The above and other objects and features of the present disclosure will become more apparent by describing in detail embodiments thereof with reference to the accompanying drawings.

FIG. 1 is a block diagram of a display module according to an embodiment of the present disclosure.

FIG. 2 is a plan view of a display panel according to an embodiment of the present disclosure.

FIG. 3 is a view illustrating an arrangement of pixel circuits according to an embodiment of the present disclosure.

FIG. 4 is a timing diagram illustrating changes in data signals applied to a first data line and a second data line according to an embodiment of the present disclosure.

FIG. 5 illustrates equivalent circuit diagrams of a first-first pixel circuit and a second-first pixel circuit according to an embodiment of the present disclosure.

FIG. 6A is a view illustrating the layout of the first-first to fourth-first pixel circuits according to an embodiment of the present disclosure.

FIG. 6B is a view illustrating a connection structure of the first-first to fourth-first pixel circuits and the first-first to fourth-first light-emitting elements according to an embodiment of the present disclosure.

FIG. 7A is a cross-sectional view of display panel illustrating a connection structure of the first-second initialization transistor and the first-second light-emitting element according to an embodiment of the present disclosure.

FIG. 7B is a cross-sectional view of display panel illustrating a connection structure of the third-second initialization transistor and the third-first light-emitting element according to an embodiment of the present disclosure.

FIG. 8 is a block diagram of an electronic device according to an embodiment of the present disclosure.

FIG. 9 illustrates schematic views of electronic devices according to various embodiments of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

As used herein, the term “and/or” includes any and all combinations of one or more of the associated listed items. Expressions such as “at least one of,” when preceding a list of elements, modify the entire list of elements and do not modify the individual elements of the list.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Embodiments of the present disclosure relate to a display panel structure in which a circuit layer and an element layer are electrically connected without the use of a separate anode extension structure. In embodiments, electrode and contact arrangements are configured so that an anode contact of a sub-pixel is positioned on a side opposite to a corresponding data line, while maintaining electrical connection between the circuit layer and the element layer.

By configuring the circuit layer and element layer in this manner, multiple sub-pixels can share a data line, thereby reducing the number of output buffers in a data driver and decreasing the total number of data lines. This arrangement can lower power consumption of the display module while maintaining effective electrical connectivity for display operation.

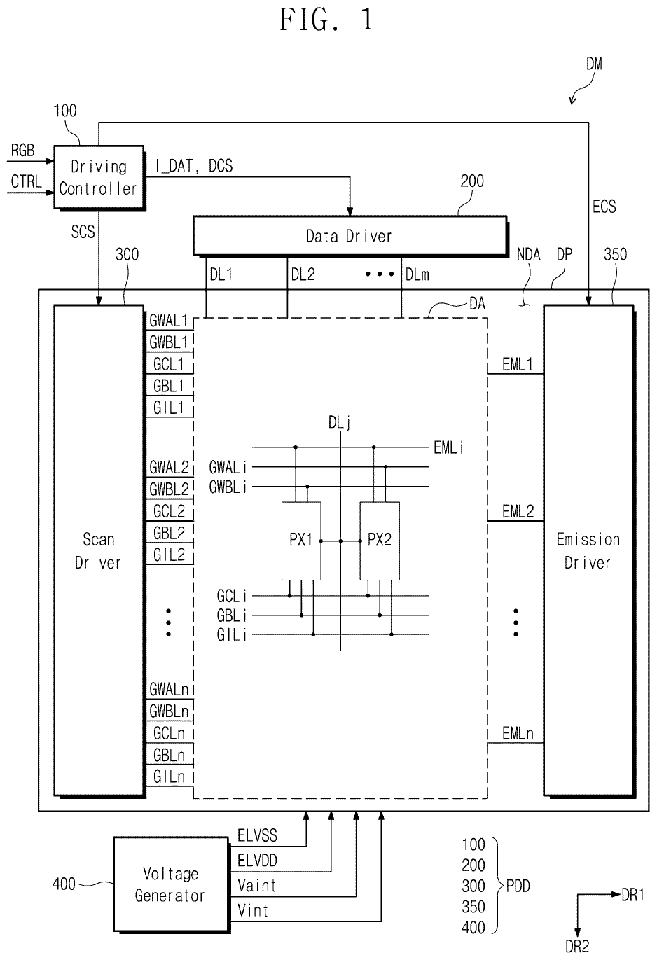

FIG. 1 is a block diagram of a display module DM according to an embodiment of the present disclosure.

Referring to FIG. 1, the display module DM may be activated in response to an electrical signal to display an image. The display module DM may be applied to electronic devices such as, for example, a smart watch, a tablet computer, a notebook computer, a computer, a smart television, and the like. The display module DM may also be referred to as a display device.

The display module DM includes a display panel DP and a panel driver PDD that drives the display panel DP. In an embodiment of the present disclosure, the panel driver PDD may include a driving controller 100, a data driver (or, a data driver circuit) 200, a scan driver (or, a scan driver circuit) 300, an emission driver (or, an emission driver circuit) 350, and a voltage generator 400.

The driving controller 100 receives an image signal RGB and a control signal CTRL. The driving controller 100 generates image data I_DAT by converting the data format of the image signal RGB according to the specification of an interface with the data driver 200. The driving controller 100 outputs a first control signal DCS, a second control signal SCS, and a third control signal ECS.

The data driver 200 receives the first control signal DCS and the image data I_DAT from the driving controller 100. The data driver 200 converts the image data I_DAT into data signals and outputs the data signals to a plurality of data lines DL1 to DLm (here, m being an integer of 1 or more) that will be described below. The data signals are analog data voltages corresponding to grayscale values of the image data I_DAT.

The voltage generator 400 generates voltages utilized for an operation of the display panel DP. In an embodiment of the present disclosure, the voltage generator 400 generates a first driving voltage ELVDD, a second driving voltage ELVSS, a first initialization voltage Vint, and a second initialization voltage Vaint. The first initialization voltage Vint may have a voltage level different from that of the second initialization voltage Vaint.

The scan driver 300 receives the second control signal SCS from the driving controller 100. The second control signal SCS may include a start signal to start an operation of the scan driver 300 and a plurality of clock signals. The scan driver 300 generates a plurality of scan signals and sequentially outputs the plurality of scan signals to scan lines to be described below. The emission driver 350 may output emission control signals to emission control lines EML1 to EMLn (here, n being an integer of 1 or more), which will be described below, in response to the third control signal ECS from the driving controller 100. In an embodiment, the scan driver 300 and the emission driver 350 may be integrated into one circuit.

The scan driver 300 outputs initialization scan signals to initialization scan lines GIL1 to GILn of the display panel DP and outputs compensation scan signals to compensation scan lines GCL1 to GCLn of the display panel DP. The scan driver 300 outputs first write scan signals (or, referred to as first scan signals) to first write scan lines GWAL1 to GWALn (or, referred to as first scan lines) of the display panel DP and outputs second write scan signals (or, referred to as second scan signals) to second write scan lines GWBL1 to GWBLn (or, referred to as second scan lines) of the display panel DP. The scan driver 300 outputs black scan signals to black scan lines GBL1 to GBLn of the display panel DP.

The display panel DP includes the initialization scan lines GIL1 to GILn, the compensation scan lines GCL1 to GCLn, the first write scan lines GWAL1 to GWALn, the second write scan lines GWBL1 to GWBLn, the black scan lines GBL1 to GBLn, the emission control lines EML1 to EMLn, the data lines DL1 to DLm, and pixels. A display area DA and a non-display area NDA are defined in the display panel DP. The initialization scan lines GIL1 to GILn, the compensation scan lines GCL1 to GCLn, the first write scan lines GWAL1 to GWALn, the second write scan lines GWBL1 to GWBLn, the black scan lines GBL1 to GBLn, the emission control lines EML1 to EMLn, the data lines DL1 to DLm, and the pixels may be disposed in the display area DA. The initialization scan lines GIL1 to GILn, the compensation scan lines GCL1 to GCLn, the first write scan lines GWAL1 to GWALn, the second write scan lines GWBL1 to GWBLn, the black scan lines GBL1 to GBLn, and the emission control lines EML1 to EMLn extend in a first direction DR1 and are spaced apart from one another in a second direction DR2. The data lines DL1 to DLm extend in the second direction DR2 and are spaced apart from one another in the first direction DR1.

The scan driver 300 and the emission driver 350 may be disposed in the non-display area NDA of the display panel DP. In an embodiment of the present disclosure, the scan driver 300 is disposed adjacent to a first side of the display area DA, and the emission driver 350 is disposed adjacent to a second side of the display area DA that faces away from the first side. Although the scan driver 300 and the emission driver 350 are disposed on the opposite sides of the display area DA in the embodiment illustrated in FIG. 1, the present disclosure is not limited thereto. For example, the scan driver 300 and the emission driver 350 may be disposed adjacent to one of the first side and the second side of the display panel DP.

The plurality of pixels are electrically connected to the initialization scan lines GIL1 to GILn, the compensation scan lines GCL1 to GCLn, the black scan lines GBL1 to GBLn, the emission control lines EML1 to EMLn, and the data lines DL1 to DLm, respectively. The plurality of pixels are connected to one of the first write scan lines GWAL1 to GWALn and the second write scan lines GWBL1 to GWBLn. Accordingly, each of the plurality of pixels may be electrically connected to four scan lines and one emission control line. However, without being limited thereto, the number of scan lines connected to each pixel and the number of emission control lines connected to each pixel may be varied.

Among pixels disposed in the same row, two pixels adjacent to each other may be commonly connected to one data line and may be connected to different write scan lines. For example, as illustrated in FIG. 1, a first pixel PX1 among pixels in the i-th row may be connected to the i-th initialization scan line GILi, the i-th compensation scan line GCLi, the first-i-th write scan line GWALi, the i-th black scan line GBLi, the i-th emission control line EMLi, and the j-th data line DLj. Here, i is an integer greater than or equal to 1 and less than or equal to n, and j is an integer greater than or equal to 1 and less than or equal to m. In addition, a second pixel PX2 among the pixels in the i-th row may be connected to the i-th initialization scan line GILi, the i-th compensation scan line GCLi, the second-i-th write scan line GWBLi, the i-th black scan line GBLi, the i-th emission control line EMLi, and the j-th data line DLj.

In this configuration according to an embodiment, the shared connection of the first pixel PX1 and the second pixel PX2 to the same j-th data line DLj enables the data driver 200 to alternately supply different color data signals to each pixel during distinct activation periods determined by the first-i-th write scan line GWALi and the second-i-th write scan line GWBLi. For example, during a first period of the corresponding horizontal scan, the first pixel PX1 may receive a first color data signal (such as a first color data signal RD described below) in response to activation of the first-i-th write scan line GWALi, while during a subsequent period of the same horizontal scan, the second pixel PX2 may receive a second color data signal (such as a second color data signal BD described below) in response to activation of the second-i-th write scan line GWBLi. By synchronizing the scan signals with the data signals in this manner, two adjacent pixel circuits can be independently driven for different colors without the need for separate data lines, thereby supporting a reduced data line count while maintaining full-color operation.

When the number of pixels disposed in one pixel row within the display panel DP is x, the number of data lines DL1 to DLm may be m. In this case, m that is the number of data lines DL1 to DLm may be half of x that is the number of pixels disposed in one pixel row. If the number of data lines DL1 to DLm is decreased compared to the number of pixels disposed in one pixel row, the power consumed when the data voltages are output to the data lines DL1 to DLm may be reduced. In addition, as the number of output terminals of the data driver 200 is decreased, the manufacturing cost of the data driver 200 may be reduced.

In an embodiment, reducing the number of data lines DL1 to DLm to about one-half of the total number of pixels in a row may decrease the number of output buffers in the data driver 200, thereby lowering the data driver's 200 circuit complexity, physical footprint, and manufacturing cost. Fewer data lines also reduce the total capacitive load driven by the output buffers, which in turn reduces power consumption during image display. Moreover, the decreased routing density in the display panel DP may allow greater design flexibility for the arrangement of pixel circuits and light-emitting elements, potentially improving the aperture ratio and enabling layout configurations in which the backplane circuit and emissive portions are connected without additional anode extension structures.

Each of the plurality of pixels includes a light-emitting element and a pixel circuit that controls light emission of the light-emitting element. The pixel circuit may include one or more transistors and one or more capacitors. The scan driver 300 and the emission driver 350 may be directly formed in the non-display area NDA of the display panel DP through the same process as the transistors of the pixel circuit.

Each of the plurality of pixels receives the first driving voltage ELVDD, the second driving voltage ELVSS, the first initialization voltage Vint, and the second initialization voltage Vaint from the voltage generator 400.

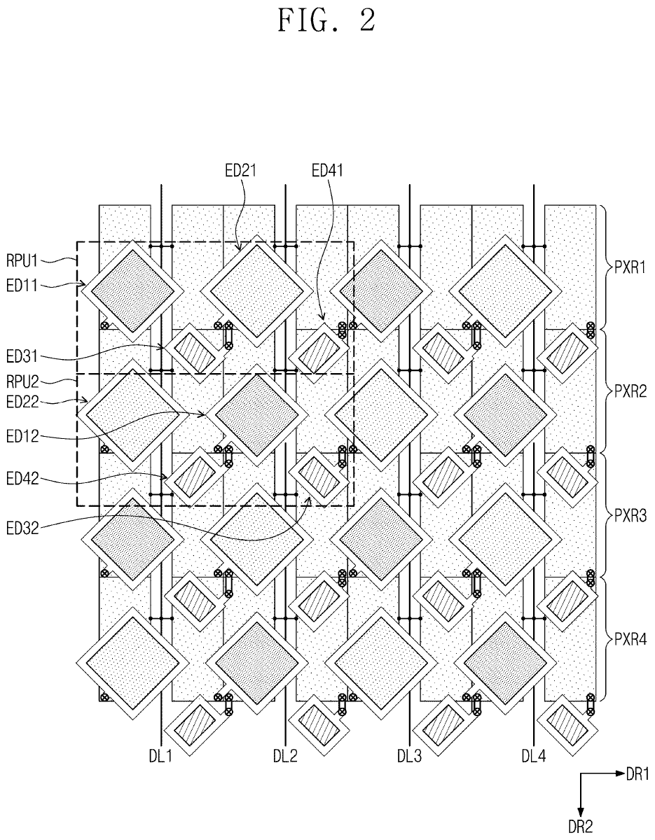

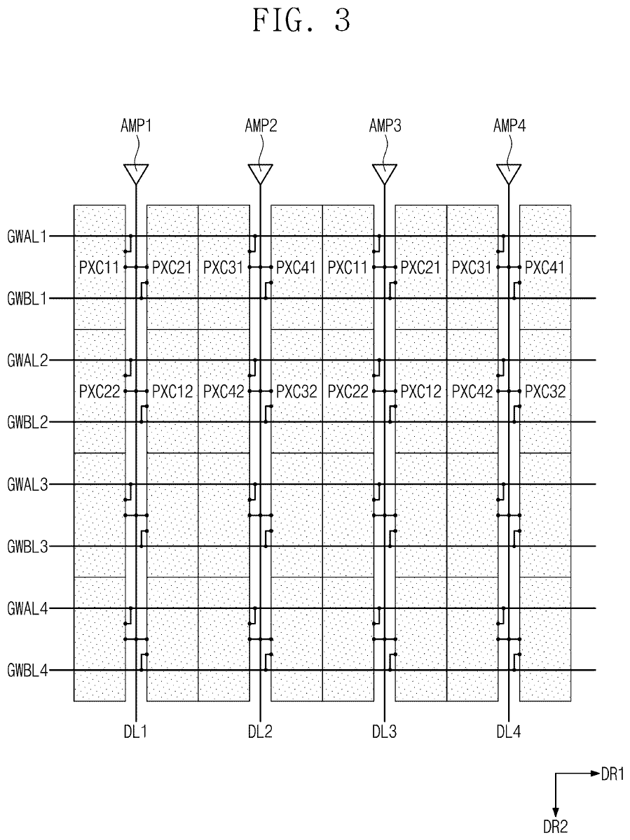

FIG. 2 is a plan view of the display panel DP according to an embodiment of the present disclosure. FIG. 3 is a view illustrating an arrangement of pixel circuits according to an embodiment of the present disclosure.

Referring to FIGS. 1 and 2, a plurality of pixels are disposed in the display area DA of the display panel DP. The plurality of pixels may be arranged in the first direction DR1 and the second direction DR2. Each of the pixels includes a light-emitting element and a pixel circuit. Sets of pixels arranged in the first direction DR1 are referred to as pixel rows, and sets of pixels arranged in the second direction DR2 are referred to as pixel columns. Among the plurality of pixel rows, odd-numbered pixel rows have the same structure, and even-numbered pixel rows have the same structure. Accordingly, the structure of the first pixel row (that is, one of the odd-numbered pixels rows) and the structure of the second pixel row (that is, one of the even-numbered pixel rows) will be described in detail with reference to FIG. 2, and description of the remaining pixel rows will be omitted.

First pixel units RPU1 are disposed in the first pixel row PXR1, and second pixel units RPU2 are disposed in the second pixel row PXR2. Each of the first pixel units RPU1 includes four pixel circuits and four light-emitting elements, and each of the second pixel units RPU2 includes four pixel circuits and four light-emitting elements. The four pixel circuits included in the first pixel unit RPU1 are referred to as the first-first pixel circuit PXC11 (or, referred to as the first pixel circuit), the second-first pixel circuit PXC21 (or, referred to as the second pixel circuit), the third-first pixel circuit PXC31 (or, referred to as the third pixel circuit), and the fourth-first pixel circuit PXC41 (or, referred to as the fourth pixel circuit). The four light-emitting elements included in the first pixel unit RPU1 are referred to as the first-first light-emitting element ED11 (or, referred to as the first light-emitting element), the third-first light-emitting element ED31 (or, referred to as the third light-emitting element), the second-first light-emitting element ED21 (or, referred to as the second light-emitting element), and the fourth-first light-emitting element ED41 (or, referred to as the fourth light-emitting element). The first-first light-emitting element ED11 is connected to the first-first pixel circuit PXC11, the second-first light-emitting element ED21 is connected to the second-first pixel circuit PXC21, the third-first light-emitting element ED31 is connected to the third-first pixel circuit PXC31, and the fourth-first light-emitting element ED41 is connected to the fourth-first pixel circuit PXC41.

The four pixel circuits included in the second pixel unit RPU2 are referred to as the first-second pixel circuit PXC12, the second-second pixel circuit PXC22, the third-second pixel circuit PXC32, and the fourth-second pixel circuit PXC42. The four light-emitting elements included in the second pixel unit RPU2 are referred to as the first-second light-emitting element ED12, the second-second light-emitting element ED22, the third-second light-emitting element ED32, and the fourth-second light-emitting element ED42. The first-second light-emitting element ED12 is connected to the first-second pixel circuit PXC12, the second-second light-emitting element ED22 is connected to the second-second pixel circuit PXC22, the third-second light-emitting element ED32 is connected to the third-second pixel circuit PXC32, and the fourth-second light-emitting element ED42 is connected to the fourth-second pixel circuit PXC42.

In an embodiment of the present disclosure, the first-first light-emitting element ED11 and the first-second light-emitting element ED12 output light of a first color, the second-first light-emitting element ED21 and the second-second light-emitting element ED22 output light of a second color, and the third-first light-emitting element ED31, the third-second light-emitting element ED32, the fourth-first light-emitting element ED41, and the fourth-second light-emitting element ED42 output light of a third color. The light of the first color may be red light, the light of the second color may be blue light, and the light of the third color may be green light.

In the first pixel unit RPU1, the first-first pixel circuit PXC11, the second-first pixel circuit PXC21, the third-first pixel circuit PXC31, and the fourth-first pixel circuit PXC41 are sequentially arranged in the first direction DR1, and in the second pixel unit RPU2, the second-second pixel circuit PXC22, the first-second pixel circuit PXC12, the fourth-second pixel circuit PXC42, and the third-second pixel circuit PXC32 are sequentially arranged in the first direction DR1. In the first pixel unit RPU1, the first-first light-emitting element ED11, the third-first light-emitting element ED31, the second-first light-emitting element ED21, and the fourth-first light-emitting element ED41 are sequentially arranged in the first direction DR1, and in the second pixel unit RPU2, the second-second light-emitting element ED22, the fourth-second light-emitting element ED42, the first-second light-emitting element ED12, and the third-second light-emitting element ED32 are sequentially arranged in the first direction DR1.

The first-first pixel circuit PXC11 and the second-first pixel circuit PXC21 are commonly connected to one data line (e.g., the first data line DL1), and the third-first pixel circuit PXC31 and the fourth-first pixel circuit PXC41 are commonly connected to another data line (e.g., the second data line DL2). The first-second pixel circuit PXC12 and the second-second pixel circuit PXC22 are commonly connected to the one data line (e.g., the first data line DL1), and the third-second pixel circuit PXC32 and the fourth-second pixel circuit PXC42 are commonly connected to the other data line (e.g., the second data line DL2). That is, two pixel circuits adjacent to each other in the first direction DR1 may share one data line.

In an embodiment, by configuring two adjacent pixel circuits, such as the first-first pixel circuit PXC11 and the second-first pixel circuit PXC21, to share a common data line (e.g., the first data line DL1) while being connected to different write scan lines, the display panel DP can alternately deliver different color data signals to each pixel circuit within the same horizontal scan period. This structural approach may effectively reduce the total number of data lines needed for the panel, lowering the count of output buffers in the data driver 200 and decreasing the capacitive loading of each output channel. As a result, both power consumption and driver circuit complexity may be reduced, while maintaining the ability to address each pixel circuit with independent color data.

The first-first pixel circuit PXC11 and the second-second pixel circuit PXC22 are disposed in the same column (that is, the first pixel column), and the second-first pixel circuit PXC21 and the first-second pixel circuit PXC12 are disposed in the same column (that is, the second pixel column). The third-first pixel circuit PXC31 and the fourth-second pixel circuit PXC42 are disposed in the same column (that is, the third pixel column), and the fourth-first pixel circuit PXC41 and the third-second pixel circuit PXC32 are disposed in the same column (that is, the fourth pixel column).

In the first pixel unit RPU1, some of the first-first pixel circuit PXC11, the second-first pixel circuit PXC21, the third-first pixel circuit PXC31, and the fourth-first pixel circuit PXC41 are connected to the first-first write scan line GWAL1, and the other pixel circuits are connected to the second-first write scan line GWBL1. Specifically, the first-first pixel circuit PXC11 and the third-first pixel circuit PXC31 are connected to the first-first write scan line GWAL1 (or, referred to as the first-first scan line), and the second-first pixel circuit PXC21 and the fourth-first pixel circuit PXC41 are connected to the second-first write scan line GWBL1 (or, referred to as the second-first scan line). In the second pixel unit RPU2, some of the first-second pixel circuit PXC12, the second-second pixel circuit PXC22, the third-second pixel circuit PXC32, and the fourth-second pixel circuit PXC42 are connected to the first-second write scan line GWAL2 (or, referred to as the first-second scan line), and the other pixel circuits are connected to the second-second write scan line GWBL2 (or, referred to as the second-second scan line). Specifically, the second-second pixel circuit PXC22 and the fourth-second pixel circuit PXC42 are connected to the first-second write scan line GWAL2, and the first-second pixel circuit PXC12 and the third-second pixel circuit PXC32 are connected to the second-second write scan line GWBL2.

In an embodiment, the pairing of pixel circuits to different write scan lines within each pixel unit, such as the connection of the first-first pixel circuit PXC11 and the third-first pixel circuit PXC31 to the first-first write scan line GWAL1, and the second-first pixel circuit PXC21 and the fourth-first pixel circuit PXC41 to the second-first write scan line GWBL1, may enable precise timing control for sequential color data delivery over shared data lines. This may enable each pixel circuit to be activated in a different sub-period of the same horizontal scan, preventing interference between color channels and supporting high-quality image rendering despite the reduced number of data lines.

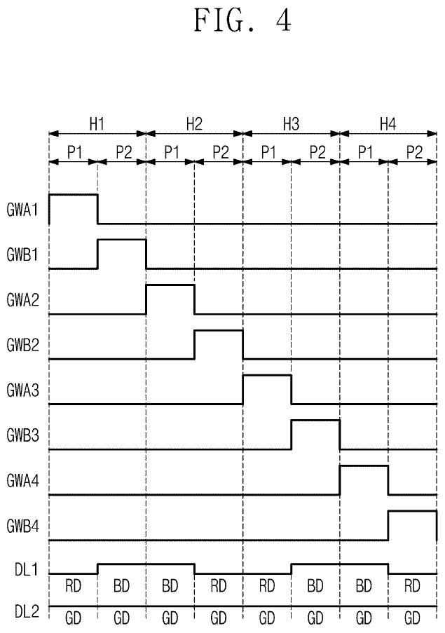

FIG. 4 is a timing diagram illustrating changes in data signals applied to the first data line and the second data line according to an embodiment of the present disclosure.

Referring to FIGS. 3 and 4, first-first to first-fourth write scan signals GWA1 to GWA4 are applied to the first-first to first-fourth write scan lines GWAL1 to GWAL4, respectively, and second-first to second-fourth write scan signals GWB1 to GWB4 are applied to the second-first to second-fourth write scan lines GWBL1 to GWBL4, respectively.

The first-first write scan signal GWA1 and the second-first write scan signal GWB1 are activated in different periods, and the first-second write scan signal GWA2 and the second-second write scan signal GWB2 are activated in different periods. For example, when the activation period of the first pixel row PXR1 is referred to as the first horizontal scan period H1, the first-first write scan signal GWA1 is activated during the first period P1 of the first horizontal scan period H1, and the second-first write scan signal GWB1 is activated during the second period P2 of the first horizontal scan period H1. When the activation period of the second pixel row PXR2 is referred to as the second horizontal scan period H2, the first-second write scan signal GWA2 is activated during the first period P1 of the second horizontal scan period H2, and the second-second write scan signal GWB2 is activated during the second period P2 of the second horizontal scan period H2. The second horizontal scan period H2 follows the first horizontal scan period H1. In an embodiment of the present disclosure, the first period P1 and the second period P2 may have the same duration time. That is, when the duration time of each of the first horizontal scan period H1 and the second horizontal scan period H2 is defined as 1 H, the duration time of each of the first period P1 and the second period P2 may be 0.5 H.

The first-third write scan signal GWA3 and the second-third write scan signal GWB3 are activated in different periods, and the first-fourth write scan signal GWA4 and the second-fourth write scan signal GWB4 are activated in different periods. For example, when the activation period of the third pixel row PXR3 is referred to as the third horizontal scan period H3, the first-third write scan signal GWA3 is activated during the first period P1 of the third horizontal scan period H3, and the second-third write scan signal GWB3 is activated during the second period P2 of the third horizontal scan period H3. When the activation period of the fourth pixel row PXR4 is referred to as the fourth horizontal scan period H4, the first-fourth write scan signal GWA4 is activated during the first period P1 of the fourth horizontal scan period H4, and the second-fourth write scan signal GWB4 is activated during the second period P2 of the fourth horizontal scan period H4.

In an embodiment, by allocating distinct sub-periods P1 and P2 within each horizontal scan period H1 to H4 to different write scan lines associated with pixel circuits sharing a common data line, the display panel DP can sequentially supply distinct color data to each pixel circuit without interference. This time-division control may allow two pixels to share a single data line while still receiving independent image data, thereby reducing the total number of data lines and corresponding output buffers. As a result, the configuration may achieve lower wiring density in the display panel DP and simplify the design of peripheral driving circuitry while preserving resolution and uniform image quality.

The data driver 200 (refer to FIG. 1) may include a plurality of output buffers AMP1, AMP2, AMP3, and AMP4 that transfer data signals. For example, the plurality of output buffers AMP1, AMP2, AMP3, and AMP4 may be connected to the data lines DL1, DL2, DL3, and DL4, respectively. The number of output buffers AMP1, AMP2, AMP3, and AMP4 may be equal to the number of data lines DL1, DL2, DL3, and DL4. As described above, one data line (e.g., the first data line DL1) may be electrically connected to two pixel circuits, and accordingly the number of output buffers AMP1, AMP2, AMP3, and AMP4 may also be reduced. Thus, the power consumption of the display module DM may be reduced.

Although FIG. 3 illustrates four output buffers AMP1, AMP2, AMP3, and AMP4 and four data lines DL1, DL2, DL3, and DL4 as an example, description of a non-illustrated configuration may also be the same.

According to an embodiment, in addition to lowering power consumption, the reduction in output buffer count may simplify the physical layout of the data driver 200. For example, fewer output buffers AMP1 to AMP4 may allow for a narrower driver IC or facilitate integration into a smaller bezel region of the display device. This can contribute to a thinner overall device profile, reduced material usage in manufacturing, and potentially lower production costs for the display module DM.

The first output buffer AMP1 supplies a first color data signal RD to the first data line DL1 during the first period P1 of the first horizontal scan period H1 and supplies a second color data signal BD to the first data line DL1 during the second period P2 of the first horizontal scan period H1. The first color data signal RD is applied to the first-first pixel circuit PXC11 activated by the first-first write scan signal GWA1 during the first period P1 of the first horizontal scan period H1, and the second color data signal BD is applied to the second-first pixel circuit PXC21 activated by the second-first write scan signal GWB1 during the second period P2 of the first horizontal scan period H1.

The first output buffer AMP1 supplies the second color data signal BD to the first data line DL1 during the first period P1 of the second horizontal scan period H2 and supplies the first color data signal RD to the first data line DL1 during the second period P2 of the second horizontal scan period H2. The second color data signal BD is applied to the second-second pixel circuit PXC22 activated by the first-second write scan signal GWA2 during the first period P1 of the second horizontal scan period H2, and the first color data signal RD is applied to the first-second pixel circuit PXC12 activated by the second-second write scan signal GWB2 during the second period P2 of the second horizontal scan period H2.

This alternating assignment of first and second color data signals across sub-periods according to an embodiment may enable the panel to preserve correct subpixel ordering in the displayed image despite halving the data line count. The coordination between the first and second write scan lines GWAL1 to GWAL4 and GWBL1 to GWBL4 and the data driver outputs may result in each pixel circuit PXC11 to PXC12 and PXC21 to PXC22 receiving its intended color data without color mixing or luminance variation. Such precise timing control may maintain the intended chromatic balance and high image fidelity in full-color display output.

The color conversion cycle of the data signal applied to the first data line DL1 may be equal to the duration time of one horizontal scan period. Accordingly, an increase in power consumption that occurs as the color conversion cycle is shortened may be prevented.

The second output buffer AMP2 supplies a third color data signal GD to the second data line DL2 during the first period P1 of the first horizontal scan period H1 and supplies the third color data signal GD to the second data line DL2 during the second period P2 of the first horizontal scan period H1. The third color data signal GD is applied to the third-first pixel circuit PXC31 activated by the first-first write scan signal GWA1 during the first period P1 of the first horizontal scan period H1, and the third color data signal GD is applied to the fourth-first pixel circuit PXC41 activated by the second-first write scan signal GWB1 during the second period P2 of the first horizontal scan period H1.

The second output buffer AMP2 supplies the third color data signal GD to the second data line DL2 during the first period P1 of the second horizontal scan period H2 and supplies the third color data signal GD to the second data line DL2 during the second period P2 of the second horizontal scan period H2. The third color data signal GD is applied to the fourth-second pixel circuit PXC42 activated by the first-second write scan signal GWA2 during the first period P1 of the second horizontal scan period H2, and the third color data signal GD is applied to the third-second pixel circuit PXC32 activated by the second-second write scan signal GWB2 during the second period P2 of the second horizontal scan period H2.

The color of the data signal applied to the second data line DL2 remains constant without being changed. By making the arrangement order of the pixel circuits different from the arrangement order of the light-emitting elements as described above, an increase in power consumption that occurs due to the color conversion of the data signals applied to the data lines may be prevented.

In an embodiment, assigning a constant color data signal, such as the third color data signal GD, to specific data lines throughout each horizontal scan period further complements the shared-line driving scheme. By eliminating rapid color switching on these data lines, instantaneous current fluctuations in the data driver 200 can be reduced, leading to more stable drive characteristics. This stability can improve overall display performance, reduce electromagnetic interference, and enable more predictable power management within the display module DM.

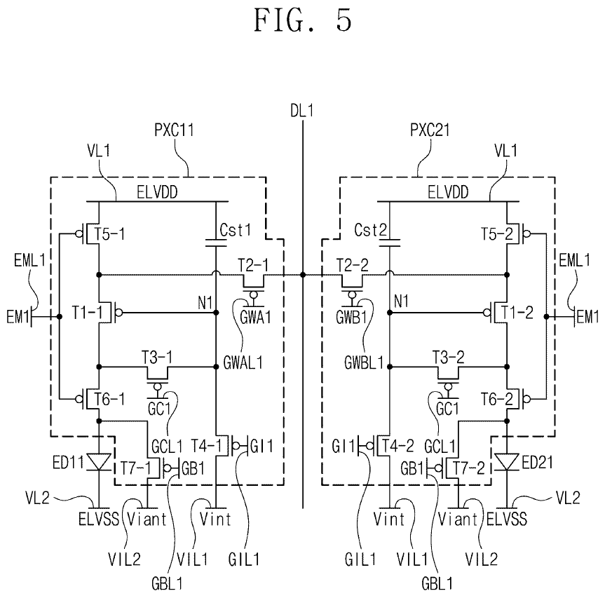

FIG. 5 illustrates equivalent circuit diagrams of the first-first pixel circuit and the second-first pixel circuit according to an embodiment of the present disclosure.

In FIG. 5, the equivalent circuit diagram of the first-first pixel circuit PXC11 connected to the first data line DL1 and the first-first write scan line GWAL1 and the equivalent circuit diagram of the second-first pixel circuit PXC21 connected to the first data line DL1 and the second-first write scan line GWBL1 are illustrated.

Referring to FIG. 5, the first-first pixel circuit PXC11 may be disposed on the left side with respect to the first data line DL1, and the second-first pixel circuit PXC21 may be disposed on the right side with respect to the first data line DL1. The first-first pixel circuit PXC11 is connected to the first-first light-emitting element ED11, and the second-first pixel circuit PXC21 is connected to the second-first light-emitting element ED21. Each of the first-first pixel circuit PXC11 and the second-first pixel circuit PXC21 may include seven transistors and one capacitor.

The first-first pixel circuit PXC11 includes a first driving transistor T1-1, a first switching transistor T2-1, a first compensation transistor T3-1, a first-first initialization transistor T4-1, a first-first emission control transistor T5-1, a first-second emission control transistor T6-1, a first-second initialization transistor T7-1, and a first capacitor Cst1. The second-first pixel circuit PXC21 includes a second driving transistor T1-2, a second switching transistor T2-2, a second compensation transistor T3-2, a second-first initialization transistor T4-2, a second-first emission control transistor T5-2, a second-second emission control transistor T6-2, a second-second initialization transistor T7-2, and a second capacitor Cst2. The first-first pixel circuit PXC11 and the second-first pixel circuit PXC21 have substantially the same circuit configuration, differing only in terms of the connection of the first switching transistor T2-1 and the second switching transistor T2-2. Therefore, the first-first pixel circuit PXC11 will be described below in detail, and repetitive description of the second-first pixel circuit PXC21 will be omitted.

At least one of the transistors T1-1 to T7-1 constituting the first-first pixel circuit PXC11 may be a transistor having a low-temperature polycrystalline silicon (LTPS) semiconductor layer. Although FIG. 5 illustrates an example that all of the transistors T1-1 to T7-1 are P-type transistors, the present disclosure is not limited thereto. For example, some of the transistors T1-1 to T7-1 may be P-type transistors, and the others may be N-type transistors. For example, the first compensation transistor T3-1 and the first-first initialization transistor T4-1 may be oxide semiconductor transistors, and the remaining transistors may be LTPS transistors.

The circuit configuration of the first-first pixel circuit PXC11 according to the present disclosure may be modified in various ways. For example, the number of transistors T1-1 to T7-1 included in the first-first pixel circuit PXC11 and the number of capacitors Cst1 included in the first-first pixel circuit PXC11 may be changed.

The first initialization scan line GIL1, the first compensation scan line GCL1, the first-first write scan line GWAL1, the first black scan line GBL1, and the first emission control line EML1 may provide the first initialization scan signal GI1, the first compensation scan signal GC1, the first-first write scan signal GWA1, the first black scan signal GB1, and the first emission control signal EM1, respectively, to the first-first pixel circuit PXC11.

In an embodiment of the present disclosure, the first-first pixel circuit PXC11 may be connected to a first driving voltage line VL1, a second driving voltage line VL2, a first initialization voltage line VIL1, and a second initialization voltage line VIL2. The first driving voltage line VL1 may provide the first driving voltage ELVDD to the first-first pixel circuit PXC11, and the second driving voltage line VL2 may provide the second driving voltage ELVSS to the first-first pixel circuit PXC11. In addition, the first initialization voltage line VIL1 may provide the first initialization voltage Vint to the first-first pixel circuit PXC11, and the second initialization voltage line VIL2 may provide the second initialization voltage Vaint to the first-first pixel circuit PXC11.

The first driving transistor T1-1 is connected between the first driving voltage line VL1 that receives the first driving voltage ELVDD and the first-first light-emitting element ED11. The first driving transistor T1-1 includes a first electrode connected with the first driving voltage line VL1 via the first-first emission control transistor T5-1, a second electrode connected with the anode electrode of the first-first light-emitting element ED11 via the first-first emission control transistor T5-1, and a third electrode (e.g., a gate electrode) connected with one end of the first capacitor Cst1 (e.g., a first node N1). The first driving transistor T1-1 may be connected with or separated from the first data line DL1 depending on a switching operation of the first switching transistor T2-1. The first capacitor Cst1 is connected between the third electrode of the first driving transistor T1-1 and the first driving voltage line VL1.

The first switching transistor T2-1 is connected between the first data line DL1 and the first electrode of the first driving transistor T1-1. The first switching transistor T2-1 includes a first electrode connected with the first data line DL1, a second electrode connected with the first electrode of the first driving transistor T1-1, and a third electrode (e.g., a gate electrode) connected with the first-first write scan line GWAL1. The first switching transistor T2-1 is turned on in response to the first-first write scan signal GWA1 transferred through the first-first write scan line GWAL1 and is connected with the first data line DL1. Accordingly, the first color data signal RD (refer to FIG. 4) applied to the first data line DL1 may be provided to the first electrode of the first driving transistor T1-1.

In an embodiment, supplying the first color data signal RD to the first driving transistor T1-1 via the first switching transistor T2-1 under the control of the first-first write scan signal GWA1 may result in each pixel circuit receiving color data at precisely timed intervals, thereby reducing data interference. The controlled timing may allow adjacent pixels connected to the same first data line DL1 to store their respective data voltages in their capacitors Cst1 and Cst2 without crosstalk, thereby preserving intended image resolution.

The first compensation transistor T3-1 is connected between the second electrode of the first driving transistor T1-1 and the first node N1. The first compensation transistor T3-1 includes a first electrode connected with the third electrode of the first driving transistor T1-1, a second electrode connected with the second electrode of the first driving transistor T1-1, and a third electrode (e.g., a gate electrode) connected with the first compensation scan line GCL1. The first compensation transistor T3-1 may be turned on in response to the first compensation scan signal GC1 transferred through the first compensation scan line GCL1 and may diode-connect the first driving transistor T1-1 by connecting the third electrode and the second electrode of the first driving transistor T1-1.

The first-first initialization transistor T4-1 is connected between the first initialization voltage line VIL1 to which the first initialization voltage Vint is applied and the first node N1. The first-first initialization transistor T4-1 includes a first electrode connected with the first initialization voltage line VIL1 to which the first initialization voltage Vint is transferred, a second electrode connected with the first node N1, and a third electrode (e.g., a gate electrode) connected with the first initialization scan line GIL1. The first-first initialization transistor T4-1 is turned on in response to the first initialization scan signal GI1 transferred through the first initialization scan line GIL1. The turned-on first-first initialization transistor T4-1 initializes the potential of the third electrode of the first driving transistor T1-1 (that is, the potential of the first node N1) by transferring the first initialization voltage Vint to the first node N1.

The first-first emission control transistor T5-1 includes a first electrode connected with the first driving voltage line VL1, a second electrode connected with the first electrode of the first driving transistor T1-1, and a third electrode (e.g., a gate electrode) connected to the first emission control line EML1.

The first-second emission control transistor T6-1 includes a first electrode connected with the second electrode of the first driving transistor T1-1, a second electrode connected to the anode electrode of the first-first light-emitting element ED11, and a third electrode (e.g., a gate electrode) connected to the first emission control line EML1.

The first-first emission control transistor T5-1 and the first-second emission control transistor T6-1 are simultaneously turned on in response to the first emission control signal EM1 transferred through the first emission control line EML1. The first driving voltage ELVDD applied through the turned-on first-first emission control transistor T5-1 may be compensated for through the diode-connected first driving transistor T1-1 and may then be transferred to the first-first light-emitting element ED11.

The first-second initialization transistor T7-1 includes a first electrode connected to the second initialization voltage line VIL2 to which the second initialization voltage Vaint is transferred, a second electrode connected with the second electrode of the first-second emission control transistor T6-1, and a third electrode (e.g., a gate electrode) connected with the first black scan line GBL1. The second initialization voltage Vaint may have a voltage level lower than or equal to the voltage level of the first initialization voltage Vint.

The first-second initialization transistor T7-1 is turned on in response to the first black scan signal GB1 transferred through the first black scan line GBL1. The second initialization voltage Vaint applied through the turned-on first-second initialization transistor T7-1 may be transferred to the anode electrode of the first-first light-emitting element ED11. Accordingly, the anode electrode of the first-first light-emitting element ED11 may be initialized to the second initialization voltage Vaint.

The second-first pixel circuit PXC21 includes the second driving transistor T1-2, the second switching transistor T2-2, the second compensation transistor T3-2, the second-first initialization transistor T4-2, the second-first emission control transistor T5-2, the second-second emission control transistor T6-2, the second-second initialization transistor T7-2, and the second capacitor Cst2.

The second switching transistor T2-2 is connected between the first data line DL1 and the first electrode of the second driving transistor T1-2. The second switching transistor T2-2 includes a first electrode connected with the first data line DL1, a second electrode connected with the first electrode of the second driving transistor T1-2, and a third electrode (e.g., a gate electrode) connected with the second-first write scan line GWBL1. The second switching transistor T2-2 is turned on in response to the second-first write scan signal GWB1 transferred through the second-first write scan line GWBL1 and is connected with the first data line DL1. Accordingly, the second color data signal BD (refer to FIG. 4) applied to the first data line DL1 may be provided to the first electrode of the second driving transistor T1-2.

That is, the first switching transistor T2-1 of the first-first pixel circuit PXC11 and the second switching transistor T2-2 of the second-first pixel circuit PXC21 are commonly connected to the first data line DL1, but are connected to different write scan lines. Accordingly, the first switching transistor T2-1 and the second switching transistor T2-2 may be turned on at different timings in response to the different write scan signals GWA1 and GWB1, respectively, and thus may receive the different color data signals RD and BD, respectively.

In this time-division driving scheme according to an embodiment, the use of separate write scan signals GWA1 and GWB1 for the two pixel circuits connected to the same first data line DL1 may enable each pixel to receive and hold its color data voltage before the other begins writing. This arrangement may avoid simultaneous loading on the data line and prevent partial voltage overlap that could degrade image quality. The resulting operational separation supports accurate color reproduction in hybrid display modes, including when transitioning between two-dimensional and three-dimensional display regions.

The second compensation transistor T3-2 of the second-first pixel circuit PXC21 is connected to the first compensation scan line GCL1 together with the first compensation transistor T3-1 of the first-first pixel circuit PXC11, and the second-first initialization transistor T4-2 of the second-first pixel circuit PXC21 is connected to the first initialization voltage line VIL1 together with the first-first initialization transistor T4-1 of the first-first pixel circuit PXC11. The second-first emission control transistor T5-2 and the second-second emission control transistor T6-2 of the second-first pixel circuit PXC21 are connected to the first emission control line EML1 in the same manner as the first-first emission control transistor T5-1 and the first-second emission control transistor T6-1 of the first-first pixel circuit PXC11, and the second-second initialization transistor T7-2 of the second-first pixel circuit PXC21 is connected to the first black scan line GBL1 in the same manner as the first-second initialization transistor T7-1 of the first-first pixel circuit PXC11.

In the first-first pixel circuit PXC11, the first-first light-emitting element ED11 is connected between the first-second emission control transistor T6-1 and the second driving voltage line VL2 to which the second driving voltage ELVSS is applied. The first electrode (that is, the anode electrode) of the first-first light-emitting element ED11 is connected to the second electrode of the first-second emission control transistor T6-1 and the second electrode of the first-second initialization transistor T7-1, and the second electrode (that is, the cathode electrode) of the first-first light-emitting element ED11 is connected to the second driving voltage line VL2. The first-first light-emitting element ED11 emits light of the first color corresponding to the first color data signal RD (refer to FIG. 4).

In the second-first pixel circuit PXC21, the second-first light-emitting element ED21 is connected between the second-second emission control transistor T6-2 and the second driving voltage line VL2 to which the second driving voltage ELVSS is applied. The first electrode (that is, the anode electrode) of the second-first light-emitting element ED21 is connected to the second electrode of the second-second emission control transistor T6-2 and the second electrode of the second-second initialization transistor T7-2, and the second electrode (that is, the cathode electrode) of the second-first light-emitting element ED21 is connected to the second driving voltage line VL2. The second-first light-emitting element ED21 emits light of the second color corresponding to the second color data signal BD (refer to FIG. 4).

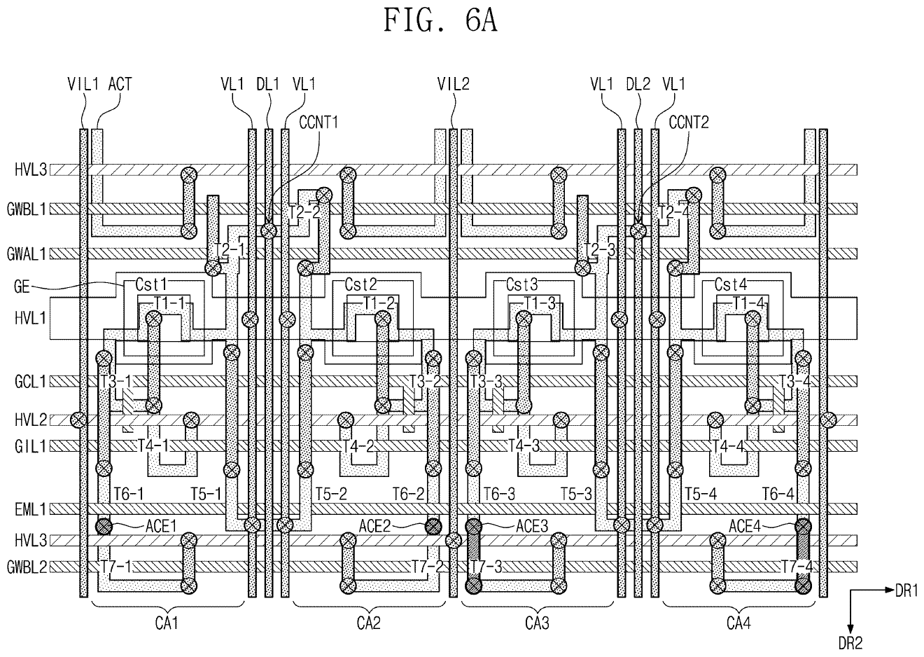

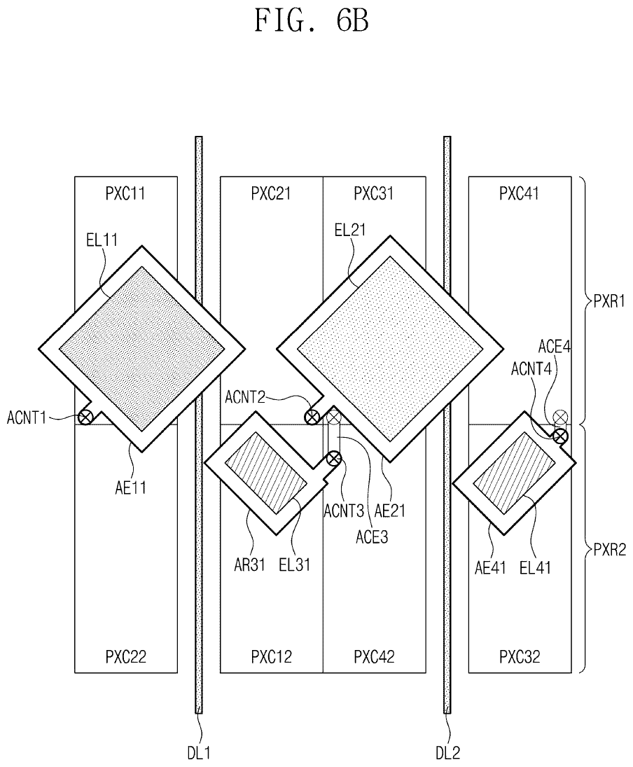

FIG. 6A is a view illustrating the layout of the first-first to fourth-first pixel circuits according to an embodiment of the present disclosure. FIG. 6B is a view illustrating a connection structure of the first-first to fourth-first pixel circuits and the first-first to fourth-first light-emitting elements according to an embodiment of the present disclosure.

Referring to FIG. 6A, four circuit areas (hereinafter, referred to as the first to fourth circuit areas CA1 to CA4) in which the first-first to fourth-first pixel circuits PXC11 to PXC41 (refer to FIG. 6B) are provided, respectively, are defined in the display panel DP.

A semiconductor pattern layer ACT may be disposed in the first to fourth circuit areas CA1 to CA4. The semiconductor pattern layer ACT may include a silicon semiconductor. For example, the silicon semiconductor may include amorphous silicon or polycrystalline silicon. For example, the semiconductor pattern layer ACT may include low-temperature polycrystalline silicon (LTPS).

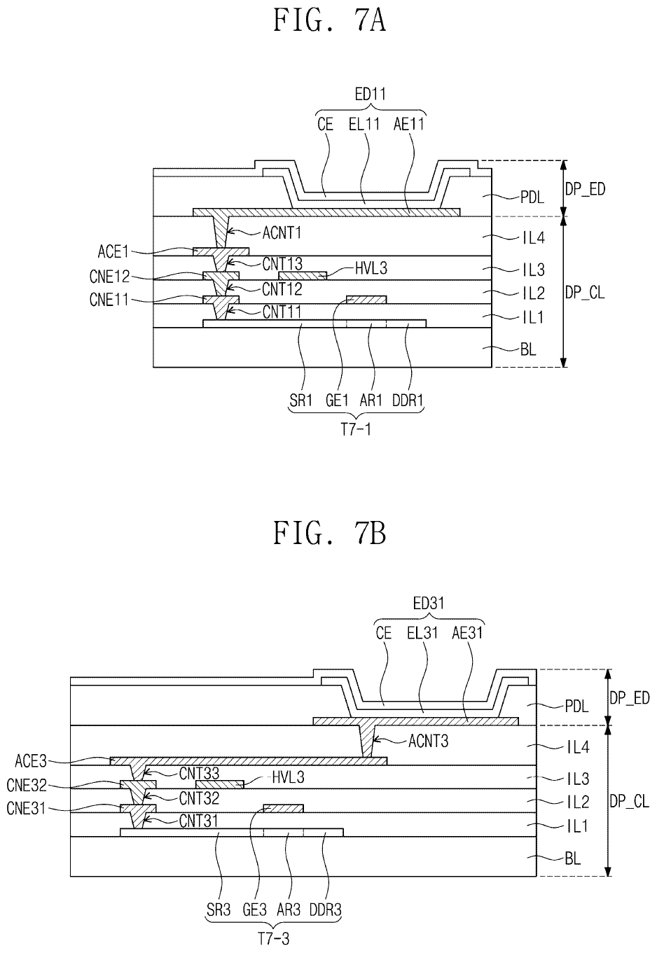

A first insulating layer IL1 (refer to FIG. 7A) is disposed on the semiconductor pattern layer ACT. The first insulating layer IL1 may be referred to as a gate insulating layer. A first gate pattern layer may be disposed on the first insulating layer IL1. The first gate pattern layer may include a metal, an alloy, conductive metal oxide, or a transparent conductive material. For example, the first gate pattern layer may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), or indium zinc oxide (IZO), but is not particularly limited thereto.

The first gate pattern layer may include gate electrodes GE, the first-first write scan line GWAL1, the second-first write scan line GWBL1, the first compensation scan line GCL1, the first initialization scan line GIL1, the first emission control line EML1, and the second-second write scan line GWBL2.

Each of the gate electrodes GE may be disposed in the shape of an island. The gate electrodes GE may overlap the semiconductor pattern layer ACT in the first to fourth circuit areas CA1 to CA4 to form the first to fourth driving transistors T1-1 to T1-4.

The first-first write scan line GWAL1, the second-first write scan line GWBL1, the first compensation scan line GCL1, the first initialization scan line GIL1, the first emission control line EML1, and the second-second write scan line GWBL2 may each extend in the first direction DR1.

The first-first write scan line GWAL1 may overlap the semiconductor pattern layer ACT in the first circuit area CA1 and the third circuit area CA3 to form the first switching transistor T2-1 and the third switching transistor T2-3, and the second-first write scan line GWBL1 may overlap the semiconductor pattern layer ACT in the second circuit area CA2 and the fourth circuit area CA4 to form the second switching transistor T2-2 and the fourth switching transistor T2-4.

The first compensation scan line GCL1 overlaps the semiconductor pattern layer ACT in the first to fourth circuit areas CA1 to CA4 to form the first to fourth compensation transistors T3-1 to T3-4, and the first initialization scan line GIL1 overlaps the semiconductor pattern layer ACT in the first to fourth circuit areas CA1 to CA4 to form the first-first to fourth-first initialization transistors T4-1 to T4-4.

The first emission control line EML1 overlaps the semiconductor pattern layer ACT in the first to fourth circuit areas CA1 to CA4 to form the first-first to fourth-first emission control transistors T5-1 to T5-4 and the first-second to fourth-second emission control transistors T6-1 to T6-4.

The second-second write scan line GWBL2 overlaps the semiconductor pattern layer ACT in the first to fourth circuit areas CA1 to CA4 to form the first-second to fourth-second initialization transistors T7-1 to T7-4.

A second insulating layer IL2 (refer to FIG. 7A) is disposed on the first gate pattern layer. The second insulating layer IL2 may include the same insulating material as the first insulating layer IL1. A second gate pattern layer may be disposed on the second insulating layer IL2. The second gate pattern layer may include a metal, an alloy, conductive metal oxide, or a transparent conductive material.

The second gate pattern layer may include a first horizontal voltage line HVL1, a second horizontal voltage line HVL2, and a third horizontal voltage line HVL3. The first to third horizontal voltage lines HVL1 to HVL3 may extend in the first direction DR1. The first driving voltage ELVDD (refer to FIG. 5) is applied to the first horizontal voltage line HVL1, the first initialization voltage Vint (refer to FIG. 5) is applied to the second horizontal voltage line HVL2, and the second initialization voltage Vaint (refer to FIG. 5) is applied to the third horizontal voltage line HVL3.

The first horizontal voltage line HVL1 may overlap the gate electrodes GE in the first to fourth circuit areas CA1 to CA4 to form the first to fourth capacitors Cst1 to Cst4. The second horizontal voltage line HVL2 is connected to the first-first to fourth-first initialization transistors T4-1 to T4-4 in the first to fourth circuit areas CA1 to CA4, and the third horizontal voltage line HVL3 is connected to the first-second to fourth-second initialization transistors T7-1 to T7-4 in the first to fourth circuit areas CA1 to CA4.

A third insulating layer IL3 (refer to FIG. 7A) is disposed on the second gate pattern layer. A data pattern layer may be disposed on the third insulating layer IL3. The data pattern layer may include a metal, an alloy, conductive metal oxide, or a transparent conductive material.

The data pattern layer includes the first data line DL1, the second data line DL2, the first driving voltage line VL1, the first initialization voltage line VIL1, and the second initialization voltage line VIL2. The first data line DL1, the second data line DL2, the first driving voltage line VL1, the first initialization voltage line VIL1, and the second initialization voltage line VIL2 extend in the second direction DR2.

Between the first circuit area CA1 and the second circuit area CA2, the first data line DL1 is connected with the semiconductor pattern layer ACT through a first common contact portion CCNT1, and between the third circuit area CA3 and the fourth circuit area CA4, the second data line DL2 is connected with the semiconductor pattern layer ACT through a second common contact portion CCNT2. The first data line DL1 may be commonly connected to the first switching transistor T2-1 and the second switching transistor T2-2 through the first common contact portion CCNT1. The first switching transistor T2-1 is connected between the first data line DL1 and the first electrode of the first driving transistor T1-1 and receives the first-first write scan signal GWA1 (refer to FIG. 4) from the first-first write scan line GWAL1. The second switching transistor T2-2 is connected between the first data line DL1 and the first electrode of the second driving transistor T1-2 and receives the second-first write scan signal GWB1 (refer to FIG. 4) from the second-first write scan line GWBL1. The second data line DL2 may be commonly connected to the third switching transistor T2-3 and the fourth switching transistor T2-4 through the second common contact portion CCNT2. The third switching transistor T2-3 is connected between the second data line DL2 and the first electrode of the third driving transistor T1-3 and receives the first-first write scan signal GWA1 from the first-first write scan line GWAL1. The fourth switching transistor T2-4 is connected between the second data line DL2 and the first electrode of the fourth driving transistor T1-4 and receives the second-first write scan signal GWB1 from the second-first write scan line GWBL1.

The first driving voltage line VL1 is connected with the first horizontal voltage line HVL1 in the first to fourth circuit areas CA1 to CA4 and receives the first driving voltage ELVDD. The first initialization voltage line VIL1 is connected with the second horizontal voltage line HVL2 and receives the first initialization voltage Vint. The second initialization voltage line VIL2 is connected with the third horizontal voltage line HVL3 and receives the second initialization voltage Vaint.

The first driving voltage line VL1 is connected with the first-first to fourth-first emission control transistors T5-1 to T5-4 in the first to fourth circuit areas CA1 to CA4.

The data pattern layer may further include first to fourth anode connecting electrodes ACE1, ACE2, ACE3, and ACE4 disposed in the first to fourth circuit areas CA1 to CA4, respectively.

The first anode connecting electrode ACE1 is connected with the first-first anode electrode AE11 of the first-first light-emitting element ED11, and the second anode connecting electrode ACE2 is connected with the second-first anode electrode AE21 of the second-first light-emitting element ED21. The first anode connecting electrode ACE1 and the second anode connecting electrode ACE2 may be disposed at positions symmetrical to each other with respect to the first data line DL1. The third anode connecting electrode ACE3 is connected with the third-first anode electrode AE31 of the third-first light-emitting element ED31, and the fourth anode connecting electrode ACE4 is connected with the fourth-first anode electrode AE41 of the fourth-first light-emitting element ED41. The third anode connecting electrode ACE3 and the fourth anode connecting electrode ACE4 may be disposed at positions symmetrical to each other with respect to the second data line DL2.

A fourth insulating layer IL4 (refer to FIG. 7A) is disposed on the data pattern layer. The first-first to fourth-first anode electrodes AE11 to AE41 of the first-first to fourth-first light-emitting elements ED11 to ED41 (refer to FIG. 2) are disposed on the fourth insulating layer IL4.

The first-first anode electrode AE11 is connected to the first anode connecting electrode ACE1 through a first anode contact portion ACNT1 provided in the fourth insulating layer IL4, and the second-first anode electrode AE21 is connected to the second anode connecting electrode ACE2 through a second anode contact portion ACNT2 provided in the fourth insulating layer IL4. That is, the first-first pixel circuit PXC11 is connected with the first-first light-emitting element ED11 at the first anode contact portion ACNT1, and the second-first pixel circuit PXC21 is connected with the second-first light-emitting element ED21 at the second anode contact portion ACNT2. The first anode contact portion ACNT1 and the second anode contact portion ACNT2 may be disposed at positions symmetrical to each other with respect to the first data line DL1.

The third-first anode electrode AE31 is connected to the third anode connecting electrode ACE3 through a third anode contact portion ACNT3 provided in the fourth insulating layer IL4, and the fourth-first anode electrode AE41 is connected to the fourth anode connecting electrode ACE4 through a fourth anode contact portion ACNT4 provided in the fourth insulating layer IL4. That is, the third-first pixel circuit PXC31 is connected with the third-first light-emitting element ED31 at the third anode contact portion ACNT3, and the fourth-first pixel circuit PXC41 is connected with the fourth-first light-emitting element ED41 at the fourth anode contact portion ACNT4. The third anode contact portion ACNT3 and the fourth anode contact portion ACNT4 are disposed at positions symmetrical to each other with respect to the second data line DL2.

The first-first to first-fourth emissive layers EL11, EL21, EL31, and EL41 may be disposed on the first-first to first-fourth anode electrodes AE11 to AE41. The first-first emissive layer EL11 outputs light of the first color (that is, red light), the second-first emissive layer EL21 outputs light of the second color (that is, blue light), and the third-first emissive layer EL31 and the fourth-first emissive layer EL41 output light of the third color (that is, green light).

In embodiments of the present disclosure, the symmetrical arrangement of the first anode connecting electrode ACE1 and the second anode connecting electrode ACE2 relative to the first data line DL1 can contribute to improved electrical uniformity between the first-first pixel circuit PXC11 and the second-first pixel circuit PXC21. By maintaining substantially equal parasitic capacitances and resistances in the respective current paths to the first-first light-emitting element ED11 and the second-first light-emitting element ED21, variations in driving voltages can be reduced. This can enhance the accuracy of compensation performed through the first compensation transistor T3-1 and the second compensation transistor T3-2, thereby supporting more consistent luminance output across the display panel.

In embodiments, the placement of the first common contact portion CCNT1 and the second common contact portion CCNT2 adjacent to the first anode connecting electrode ACE1 and the second anode connecting electrode ACE2, respectively, may also simplify routing of the first driving voltage ELVDD and the second driving voltage ELVSS within the pixel area. In such configurations, fewer crossover points between gate lines and power lines are needed, which can reduce layout complexity and enable a narrower pixel pitch. This arrangement supports higher-resolution implementations of the inventive pixel circuit configuration without increasing manufacturing difficulty.

Furthermore, the spatial positioning of the first-first light-emitting element ED11 and the second-first light-emitting element ED21 in relation to their corresponding emission control transistors T5-1, T6-1, T5-2, and T6-2 can reduce timing skew between activation signals delivered over the first emission control line EML1. By reducing differences in signal propagation distance and path impedance, the first emission control signals EM1 can be applied to both sub-pixels in a substantially synchronous manner, promoting stable color balance when the first color data signal RD and the second color data signal BD are displayed in adjacent sub-pixel regions.

FIG. 7A is a cross-sectional view of display panel DP illustrating a connection structure of the first-second initialization transistor T7-1 and the first-second light-emitting element ED11 according to an embodiment of the present disclosure, and FIG. 7B is a cross-sectional view of display panel DP illustrating a connection structure of the third-second initialization transistor T7-3 and the third-first light-emitting element ED31 according to an embodiment of the present disclosure.

Referring to FIGS. 7A and 7B, the display panel DP may include a base layer BL, a circuit layer DP_CL, and an element layer DP_ED.

The base layer BL may include a synthetic resin layer. The synthetic resin layer may include a thermosetting resin. For example, the synthetic resin layer may be a polyimide-based resin layer, and the material thereof is not particularly limited. The synthetic resin layer may include at least one of, for example, an acrylic resin, a methacrylic resin, a polyisoprene resin, a vinyl resin, an epoxy resin, a urethane-based resin, a celluosic resin, a siloxane-based resin, a polyamide resin, and a perylene-based resin. In addition, the base layer BL may include a glass substrate, a metal substrate, or an organic/inorganic composite substrate.

At least one inorganic layer is formed on the upper surface of the base layer BL. The inorganic layer may include at least one of, for example, aluminum oxide, titanium oxide, silicon oxide, silicon oxy nitride, zirconium oxide, and hafnium oxide. The inorganic layer may be formed of multiple layers.

The circuit layer DP_CL is disposed on the base layer BL. The circuit layer DP_CL includes a semiconductor pattern layer disposed on the base layer BL. The semiconductor pattern layer may include a plurality of semiconductor patterns. Each of the semiconductor patterns may include poly silicon. However, without being limited thereto, each of the semiconductor patterns may include amorphous silicon.

In FIGS. 7A and 7B, only a portion of a semiconductor pattern is illustrated. The semiconductor pattern has different electrical properties depending on whether doping is performed. The semiconductor pattern may include a doped area and a non-doped area. The doped area may be doped with an N-type dopant or a P-type dopant. A P-type transistor includes a doped area doped with a P-type dopant, and an N-type transistor includes a doped area doped with an N-type dopant.

The doped area has a higher conductivity than the non-doped area and substantially serves as an electrode of a transistor or a signal line. The non-doped area substantially corresponds to a channel part of the transistor. In other words, one portion of the semiconductor pattern may be the channel part of the transistor, and another portion may be the source or drain of the transistor.

As illustrated in FIG. 7A, the first electrode SR1 (or, the source), the channel part AR1, and the second electrode DDR1 (or, the drain) of the first-second initialization transistor T7-1 are formed from the semiconductor pattern. The first electrode SR1 and the second electrode DDR1 of the first-second initialization transistor T7-1 extend from the channel part AR1 in opposite directions. As illustrated in FIG. 7B, the first electrode SR3 (or, the source), the channel part AR3, and the second electrode DDR3 (or, the drain) of the third-second initialization transistor T7-3 are formed from the semiconductor pattern. The first electrode SR3 and the second electrode DDR3 of the third-second initialization transistor T7-3 extend from the channel part AR3 in opposite directions.

In an embodiment, the symmetrical arrangement of the first-second initialization transistor T7-1 and the third-second initialization transistor T7-3, including the alignment of the first electrode SR1, the channel part AR1, and the second electrode DDR1, with the first electrode SR3, the channel part AR3, and the second electrode DDR3, may facilitate substantially identical electrical path lengths and parasitic capacitances between paired transistors in adjacent sub-pixels. Such symmetry may allow the initialization voltages to be applied with minimal or reduced timing skew and voltage drop differences between the two sub-pixels, thereby improving luminance uniformity and reducing image artifacts.

The first insulating layer IL1 is disposed on the base layer BL. The first insulating layer IL1 covers the upper surface of the base layer BL and the semiconductor pattern. The first insulating layer IL1 may be an inorganic layer and/or an organic layer and may have a single-layer structure or a multi-layer structure. The first insulating layer IL1 may include at least one of, for example, aluminum oxide, titanium oxide, silicon oxide, silicon oxy nitride, zirconium oxide, and hafnium oxide. In this embodiment, the first insulating layer IL1 may be a single silicon oxide layer. Not only the first insulating layer IL1 but also the insulating layers of the circuit layer DP_CL that will be described below may be inorganic layers and/or organic layers and may have a single-layer structure or a multi-layer structure. The inorganic layers may include at least one of the aforementioned materials.

The third electrode GE1 of the first-second initialization transistor T7-1 and the third electrode GE3 of the third-second initialization transistor T7-3 are disposed on the first insulating layer IL1. The third electrode GE1 of the first-second initialization transistor T7-1 and the third electrode GE3 of the third-second initialization transistor T7-3 may be portions of the first gate pattern layer (refer to FIG. 6A) (for example, portions of the second-second write scan line GWBL2 (refer to FIG. 6A)). The third electrode GE1 of the first-second initialization transistor T7-1 overlaps the channel part AR1 of the first-second initialization transistor T7-1, and the third electrode GE3 of the third-second initialization transistor T7-3 overlaps the channel part AR3 of the third-second initialization transistor T7-3.

A first-first connecting electrode CNE11 and a third-first connecting electrode CNE31 may be additionally disposed on the first insulating layer IL1. The first-first connecting electrode CNE11 is connected to the second electrode DDR1 of the first-second initialization transistor T7-1 through a first-first contact portion CNT11 provided in the first insulating layer IL1, and the third-first connecting electrode CNE31 is connected to the second electrode DDR3 of the third-second initialization transistor T7-3 through a third-first contact portion CNT31 provided in the first insulating layer IL1.

In an embodiment, the vertical interconnection provided by the first-first connecting electrode CNE11 and the third-first connecting electrode CNE31, in conjunction with the respective contact portions CNT11 and CNT31, is configured to maintain consistent electrical resistance across paired sub-pixels, even where slight process variations occur in contact formation. This consistent resistance may aid in equalizing current flow paths to each pixel's anode, supporting balanced pixel charging during the shared-line driving sequence and reducing differential aging between the paired sub-pixels.

The second insulating layer IL2 that covers the third electrode GE1 of the first-second initialization transistor T7-1 and the third electrode GE3 of the third-second initialization transistor T7-3 is disposed on the first insulating layer IL1. The second insulating layer IL2 may be an inorganic layer and/or an organic layer and may have a single-layer structure or a multi-layer structure. In this embodiment, the second insulating layer IL2 may be a single silicon oxide layer.

The third horizontal voltage line HVL3 is disposed on the second insulating layer IL2. The third horizontal voltage line HVL3 may be connected to the first electrode SR1 of the first-second initialization transistor T7-1 and the first electrode SR3 of the third-second initialization transistor T7-3 and may apply the second initialization voltage Vaint (refer to FIG. 5). The third horizontal voltage line HVL3 may be a portion of the second gate pattern layer (refer to FIG. 6A).

In an embodiment, the third horizontal voltage line HVL3 provides a common initialization voltage to both the first electrode SR1 of the first-second initialization transistor T7-1 and the first electrode SR3 of the third-second initialization transistor T7-3. By using a shared conductive trace in this manner, the driving circuit may reduce the number of horizontal lines while enabling the paired transistors to receive initialization voltages in substantially the same phase and magnitude. This design may be utilized in, for example, a hybrid 2D/3D display, where synchronous pixel initialization across multiple regions avoids crosstalk and maintains sharp image boundaries.

A first-second connecting electrode CNE12 and a third-second connecting electrode CNE32 may be additionally disposed on the second insulating layer IL2. The first-second connecting electrode CNE12 is connected to the first-first connecting electrode CNE11 through a first-second contact portion CNT12 provided in the second insulating layer IL2, and the third-second connecting electrode CNE32 is connected to the third-first connecting electrode CNE31 through a third-second contact portion CNT32 provided in the second insulating layer IL2.

The third insulating layer IL3 that covers the third horizontal voltage line HVL3, the first-second connecting electrode CNE12, and the third-second connecting electrode CNE32 is disposed on the second insulating layer IL2. In this embodiment, the third insulating layer IL3 may be an organic layer and may have a single-layer structure or a multi-layer structure. The third insulating layer IL3 may be a single polyimide-based resin layer. Without being limited thereto, the third insulating layer IL3 may include at least one of, for example, an acrylic resin, a methacrylic resin, a polyisoprene resin, a vinyl resin, an epoxy resin, a urethane-based resin, a celluosic resin, a siloxane-based resin, a polyamide resin, and a perylene-based resin.

The first anode connecting electrode ACE1 and the third anode connecting electrode ACE3 are disposed on the third insulating layer IL3. The first anode connecting electrode ACE1 and the third anode connecting electrode ACE3 may be components included in the data pattern layer (refer to FIG. 6A).

The first anode connecting electrode ACE1 is connected to the first-second connecting electrode CNE12 through a first-third contact portion CNT13 provided in the third insulating layer IL3, and the third anode connecting electrode ACE3 is connected to the third-second connecting electrode CNE32 through a third-third contact portion CNT33 provided in the third insulating layer IL3.

The fourth insulating layer IL4 that covers the first anode connecting electrode ACE1 and the third anode connecting electrode ACE3 is disposed on the third insulating layer IL3. The fourth insulating layer IL4 may be an organic layer and may have a single-layer structure or a multi-layer structure. The element layer DP_ED is disposed on the fourth insulating layer IL4. For example, the first-first anode electrode AE11 of the first-first light-emitting element ED11 and the third-first anode electrode AE31 of the third-first light-emitting element ED31 are disposed on the fourth insulating layer IL4. The first-first anode electrode AE11 is connected to the first anode connecting electrode ACE1 through the first anode contact portion ACNT1 provided in the fourth insulating layer IL4. In an embodiment of the present disclosure, the first anode contact portion ACNT1 may overlap the first-first to first-third contact portions CNT11, CNT12, and CNT13 when viewed from above the plane. The third-first anode electrode AE31 is connected to the third anode connecting electrode ACE3 through the third anode contact portion ACNT3 provided in the fourth insulating layer IL4. In an embodiment of the present disclosure, the third anode contact portion ACNT3 may not overlap the third-first to third-third contact portions CNT31, CNT32, and CNT33 when viewed from above the plane.

In an embodiment, the overlap of the first anode contact portion ACNT1 with contact portions CNT11, CNT12, and CNT13, contrasted with the non-overlap of the third anode contact portion ACNT3 relative to contact portions CNT31, CNT32, and CNT33, may compensate for differences in parasitic capacitance and signal delay between the two sub-pixels. In embodiments, this difference in overlap geometry may aid in fine-tuning the RC characteristics of each sub-pixel's anode connection, thereby equalizing the charging behavior and further enhancing the uniformity of light emission between paired sub-pixels operating under the shared-line driving scheme.

A pixel defining layer PDL that covers the first-first anode electrode AE11 and the third-first anode electrode AE31 is disposed on the fourth insulating layer IL4. A first pixel opening OP1 and a third pixel opening OP3 that expose the first-first anode electrode AE11 and the third-first anode electrode AE31, respectively, are provided in the pixel defining layer PDL. The first-first emissive layer EL11 and the third-first emissive layer EL31 may be disposed on the first-first anode electrode AE11 and the third-first anode electrode AE31 in correspondence with the first pixel opening OP1 and the third pixel opening OP3. A structure in which the first-first emissive layer EL11 and the third-first emissive layer EL31 are subjected to patterning on a pixel-by-pixel basis is illustrated in this embodiment, but the present disclosure is not limited thereto. A common emissive layer may be commonly disposed in the plurality of pixels. In this case, the common emissive layer may generate white light or blue light. The cathode electrode CE may be commonly disposed in the plurality of pixels. The cathode electrode CE may be disposed on the first-first emissive layer EL11, the third-first emissive layer EL31, and the upper surface of the pixel defining layer PDL and may face the first-first anode electrode AE11 and the third-first anode electrode AE31.

In an embodiment, the alignment of the first-first pixel opening OP1 with the first-first anode electrode AE11, and the third pixel opening OP3 with the third-first anode electrode AE31, is configured such that the emissive layers EL11 and EL31 are positioned to improve light extraction while preserving the electrical symmetry of the paired sub-pixels. This precise alignment may aid in maintaining uniform optical output between sub-pixels that are driven in a coordinated manner, thereby preserving image quality across regions of the display where different viewing modes are selectively activated.

The display module according to an embodiment of the present disclosure may be applied to various electronic devices. An electronic device according to an embodiment may include the display module described above and may further include a module or device having other additional functions in addition to the display device.

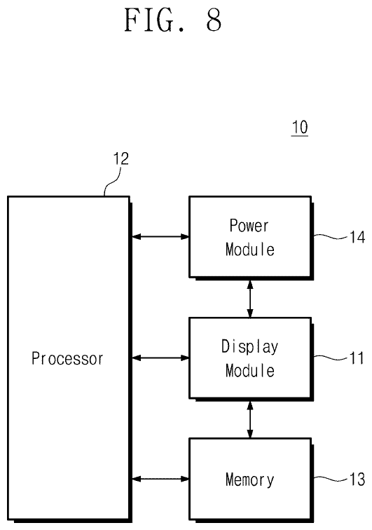

FIG. 8 is a block diagram of an electronic device according to an embodiment of the present disclosure.

Referring to FIG. 8, the electronic device 10 according to an embodiment may include a display module 11, a processor 12, a memory 13, and a power module 14.

The display module 11 displays an image based on an image signal received from the processor 12. The processor 12 controls driving of the display module 11 and provides the image signal to the display module 11. The processor 12 may include at least one of, for example, a central processing unit (CPU), an application processor (AP), a graphic processing unit (GPU), a communication processor (CP), an image signal processor (ISP), and a controller.

Data information utilized for an operation of the processor 12 or the display module 11 may be stored in the memory 13. When the processor 12 executes an application stored in the memory 13, an image signal and/or a control signal may be transferred to the display module 11, and the display module 11 may process the provided signal and may output image information through a display screen.

The power module 14 may include a power supply module, such as a power adaptor or a battery device, and a power conversion module that converts power supplied by the power supply module and generates power utilized for an operation of the electronic device 10.

At least one of the components of the electronic device 10 described above may be included in the display module according to the embodiments described above. In addition, some of the separate modules functionally included in one module may be included in the display module, and the others may be provided separately from the display module. For example, the display module 11 may be included in the display device, and the processor 12, the memory 13, and the power module 14 may be provided in the form of other devices within the electronic device 10 rather than the display device.

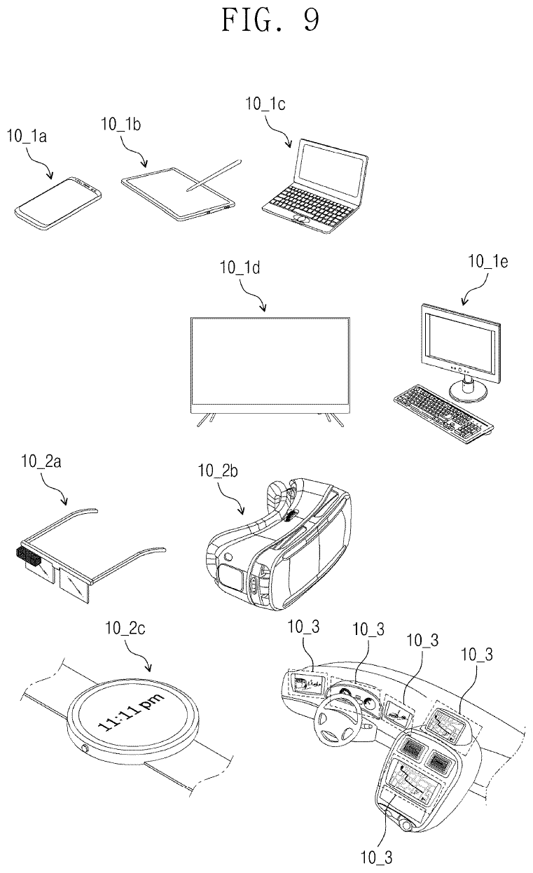

FIG. 9 illustrates schematic views of electronic devices according to various embodiments of the present disclosure.

Referring to FIG. 9, the electronic devices according to the various embodiments, to which the display module is applied, may include not only an electronic device for displaying an image, such as a smartphone 10_1a, a tablet PC 10_1b, a laptop computer 10_1c, a TV 10_1d, or a computer monitor 10_1e, but also a wearable electronic device, such as smart glasses 10_2a, a head mounted display 10_2b, or a smart watch 10_2c, and a vehicle electronic device 10_3, such as a center information display (CID) or a room mirror display disposed on an instrument panel, a center fascia, and a dashboard of a vehicle.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. In embodiments, each block, unit and/or module may be implemented by dedicated hardware, or as a combination of dedicated hardware to perform some functions and a processor (e.g., one or more programmed microprocessors and associated circuitry) to perform other functions.

In the display module according to embodiments of the present disclosure, two pixel circuits may be connected to one data line. Accordingly, the number of output buffers included in the data driver and the number of data lines may be decreased, and the power consumption of the display module may be reduced.

In addition, by making the arrangement order of the pixel circuits different from the arrangement order of the light-emitting elements, the color conversion cycle of the data signals applied to the data lines may be increased, and an increase in power consumption that occurs as the color conversion cycle is shortened may be prevented.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a first data line configured to receive a first color data signal or a second color data signal;
a second data line configured to receive a third color data signal;
a first-first scan line configured to receive a first-first scan signal;
a second-first scan line configured to receive a second-first scan signal;
a first-first pixel circuit connected to the first data line and the first-first scan line and configured to receive the first color data signal in response to the first-first scan signal;
a second-first pixel circuit connected to the first data line and the second-first scan line and configured to receive the second color data signal in response to the second-first scan signal;
a third-first pixel circuit connected to the second data line and the first-first scan line and configured to receive the third color data signal in response to the first-first scan signal;
a fourth-first pixel circuit connected to the second data line and the second-first scan line and configured to receive the third color data signal in response to the second-first scan signal;
a first-first light-emitting element connected to the first-first pixel circuit and configured to output light of a first color;
a second-first light-emitting element connected to the second-first pixel circuit and configured to output light of a second color;
a third-first light-emitting element connected to the third-first pixel circuit and configured to output light of a third color; and
a fourth-first light-emitting element connected to the fourth-first pixel circuit and configured to output the light of the third color.

2. The display device of claim 1, wherein the first-first scan line and the second-first scan line extend in a first direction,
wherein the first data line and the second data line extend in a second direction crossing the first direction, and
wherein the first-first pixel circuit, the second-first pixel circuit, the third-first pixel circuit, and the fourth-first pixel circuit are sequentially arranged in the first direction.

3. The display device of claim 2, wherein the first-first light-emitting element, the third-first light-emitting element, the second-first light-emitting element, and the fourth-first light-emitting element are sequentially arranged in the first direction.

4. The display device of claim 3, further comprising:
a first-second scan line configured to receive a first-second scan signal;
a second-second scan line configured to receive a second-second scan signal;
a first-second pixel circuit connected to the first data line and the second-second scan line and configured to receive the first color data signal in response to the second-second scan signal;
a second-second pixel circuit connected to the first data line and the first-second scan line and configured to receive the second color data signal in response to the first-second scan signal;
a third-second pixel circuit connected to the second data line and the second-second scan line and configured to receive the third color data signal in response to the second-second scan signal;
a fourth-second pixel circuit connected to the second data line and the first-second scan line and configured to receive the third color data signal in response to the first-second scan signal;
a first-second light-emitting element connected to the first-second pixel circuit and configured to output the light of the first color;
a second-second light-emitting element connected to the second-second pixel circuit and configured to output the light of the second color;
a third-second light-emitting element connected to the third-second pixel circuit and configured to output the light of the third color; and
a fourth-second light-emitting element connected to the fourth-second pixel circuit and configured to output the light of the third color.

5. The display device of claim 4, wherein the second-second pixel circuit, the first-second pixel circuit, the fourth-second pixel circuit, and the third-second pixel circuit are sequentially arranged in the first direction,
wherein the first-first pixel circuit, the second-first pixel circuit, the third-first pixel circuit, and the fourth-first pixel circuit are disposed in a first pixel row, and
wherein the second-second pixel circuit, the first-second pixel circuit, the fourth-second pixel circuit, and the third-second pixel circuit are disposed in a second pixel row.

6. The display device of claim 5, wherein the first-first pixel circuit and the second-second pixel circuit are disposed in a first pixel column,
wherein the second-first pixel circuit and the first-second pixel circuit are disposed in a second pixel column,
wherein the third-first pixel circuit and the fourth-second pixel circuit are disposed in a third pixel column, and
wherein the fourth-first pixel circuit and the third-second pixel circuit are disposed in a fourth pixel column.

7. The display device of claim 5, wherein the second-second light-emitting element, the fourth-second light-emitting element, the first-second light-emitting element, and the third-second light-emitting element are sequentially arranged in the first direction.

8. The display device of claim 7, further comprising:
a data driver circuit connected to the first data line and the second data line,
wherein the data driver circuit is configured to:
supply the first color data signal to the first data line during a first period of a first horizontal scan period and supply the second color data signal to the first data line during a second period of the first horizontal scan period;
supply the second color data signal to the first data line during a first period of a second horizontal scan period following the first horizontal scan period and supply the first color data signal to the first data line during a second period of the second horizontal scan period; and
supply the third color data signal to the second data line during the first horizontal scan period and the second horizontal scan period.

9. The display device of claim 8, wherein the first-first pixel circuit includes:
a first driving transistor; and
a first switching transistor connected between a first electrode of the first driving transistor and the first data line and configured to receive the first-first scan signal from the first-first scan line,
wherein the second-first pixel circuit includes:
a second driving transistor; and
a second switching transistor connected between a first electrode of the second driving transistor and the first data line and configured to receive the second-first scan signal from the second-first scan line,
wherein the third-first pixel circuit includes:
a third driving transistor; and
a third switching transistor connected between a first electrode of the third driving transistor and the second data line and configured to receive the first-first scan signal from the first-first scan line, and
wherein the fourth-first pixel circuit includes:
a fourth driving transistor; and
a fourth switching transistor connected between a first electrode of the fourth driving transistor and the second data line and configured to receive the second-first scan signal from the second-first scan line.

10. The display device of claim 9, wherein the first switching transistor and the third switching transistor are turned on during the first period of the first horizontal scan period and the first period of the second horizontal scan period, and
wherein the second switching transistor and the fourth switching transistor are turned on during the second period of the first horizontal scan period and the second period of the second horizontal scan period.

11. The display device of claim 1, wherein the first-first pixel circuit is connected with the first-first light-emitting element at a first anode contact portion,
wherein the second-first pixel circuit is connected with the second-first light-emitting element at a second anode contact portion, and
wherein the first anode contact portion and the second anode contact portion are disposed at positions symmetrical to each other with respect to the first data line.

12. The display device of claim 11, wherein the third-first pixel circuit is connected with the third-first light-emitting element at a third anode contact portion,
wherein the fourth-first pixel circuit is connected with the fourth-first light-emitting element at a fourth anode contact portion, and
wherein the third anode contact portion and the fourth anode contact portion are disposed at positions symmetrical to each other with respect to the second data line.

13. A display device, comprising:
a first scan line extending in a first direction;
a second scan line extending in the first direction;
a first data line extending in a second direction crossing the first direction;
a second data line extending in the second direction;
a first pixel circuit connected to the first data line and the first scan line;
a second pixel circuit connected to the first data line and the second scan line;
a third pixel circuit connected to the second data line and the first scan line;
a fourth pixel circuit connected to the second data line and the second scan line;
a first light-emitting element connected to the first pixel circuit and configured to output light of a first color;
a second light-emitting element connected to the second pixel circuit and configured to output light of a second color;
a third light-emitting element connected to the third pixel circuit and configured to output light of a third color; and
a fourth light-emitting element connected to the fourth pixel circuit and configured to output the light of the third color,
wherein the first to fourth pixel circuits are sequentially arranged in the first direction, and
wherein the first light-emitting element, the third light-emitting element, the second light-emitting element, and the fourth light-emitting element are sequentially arranged in the first direction.

14. The display device of claim 13, further comprising:
a data driver circuit connected to the first data line and the second data line,
wherein the data driver circuit is configured to:
supply a first color data signal to the first data line during a first period of a first horizontal scan period and supply a second color data signal to the first data line during a second period of the first horizontal scan period;
supply the second color data signal to the first data line during a first period of a second horizontal scan period following the first horizontal scan period and supply the first color data signal to the first data line during a second period of the second horizontal scan period; and
supply a third color data signal to the second data line during the first horizontal scan period and the second horizontal scan period.

15. The display device of claim 14, wherein the first pixel circuit includes:
a first driving transistor; and
a first switching transistor connected between a first electrode of the first driving transistor and the first data line and configured to receive a first scan signal from the first scan line,
wherein the second pixel circuit includes:
a second driving transistor; and
a second switching transistor connected between a first electrode of the second driving transistor and the first data line and configured to receive a second scan signal from the second scan line,
wherein the third pixel circuit includes:
a third driving transistor; and
a third switching transistor connected between a first electrode of the third driving transistor and the second data line and configured to receive the first scan signal from the first scan line, and
wherein the fourth pixel circuit includes:
a fourth driving transistor; and
a fourth switching transistor connected between a first electrode of the fourth driving transistor and the second data line and configured to receive the second scan signal from the second scan line.

16. The display device of claim 15, wherein the first switching transistor and the third switching transistor are turned on during the first period of the first horizontal scan period and the first period of the second horizontal scan period, and
wherein the second switching transistor and the fourth switching transistor are turned on during the second period of the first horizontal scan period and the second period of the second horizontal scan period.

17. The display device of claim 16, wherein the first period has a same duration time as the second period.

18. The display device of claim 13, wherein the first pixel circuit is connected with the first light-emitting element at a first anode contact portion,
wherein the second pixel circuit is connected with the second light-emitting element at a second anode contact portion, and
wherein the first anode contact portion and the second anode contact portion are disposed at positions symmetrical to each other with respect to the first data line.

19. The display device of claim 18, wherein the third pixel circuit is connected with the third light-emitting element at a third anode contact portion,
wherein the fourth pixel circuit is connected with the fourth light-emitting element at a fourth anode contact portion, and
wherein the third anode contact portion and the fourth anode contact portion are disposed at positions symmetrical to each other with respect to the second data line.

20. An electronic device, comprising:
a display device configured to display an image based on an image signal; and
a processor configured to control driving of the display device and provide the image signal to the display device,
wherein the display device includes:
a first scan line extending in a first direction;
a second scan line extending in the first direction;
a first data line extending in a second direction crossing the first direction;
a second data line extending in the second direction;
a first pixel circuit connected to the first data line and the first scan line;
a second pixel circuit connected to the first data line and the second scan line;
a third pixel circuit connected to the second data line and the first scan line;
a fourth pixel circuit connected to the second data line and the second scan line;
a first light-emitting element connected to the first pixel circuit and configured to output light of a first color;
a second light-emitting element connected to the second pixel circuit and configured to output light of a second color;
a third light-emitting element connected to the third pixel circuit and configured to output light of a third color; and
a fourth light-emitting element connected to the fourth pixel circuit and configured to output the light of the third color,
wherein the first to fourth pixel circuits are sequentially arranged in the first direction, and
wherein the first light-emitting element, the third light-emitting element, the second light-emitting element, and the fourth light-emitting element are sequentially arranged in the first direction.
